(19) United States
(12) Patent Application Publication
(10) Pub. No.: US 2009/0092905 A1
(43) Pub. Date: Apr. 9, 2009

(54) PHOTOMASK DEFECT CORRECTION DEVICE AND PHOTOMASK DEFECT CORRECTION METHOD

(76) Inventors: Takuya Nakaue, Chiba-shi (JP); Atsushi Uemoto, Chiba-shi (JP); Osamu Takaoka, Chiba-shi (JP)

Correspondence Address: Brinks Hofer Gilson & Lione/Seiko Instruments Inc., P.O. Box 10395, Chicago, IL, 60611, US

(21) Appl. No.: 12/145,985

(22) Filed: Jun. 25, 2008

(30) Foreign Application Priority Data
Jun. 25, 2007 (JP) JP2007-165984

(51) Int. Cl. G03F 1/14; B26D 5/00

(52) U.S. Cl. 430/5; 83/76.1

(57) ABSTRACT

Provided is a photomask defect correction method of correcting a defect on a photomask including a substrate (2) and a mask pattern (3) by cutting and removing processing a defect portion (5) based on observation data obtained through AFM observation of the photomask in advance, including: an area setting step of setting a processing area (E1) based on the observation data, and setting areas adjacent to the processing area as removing processing areas (E2) of cutting wastes for cutting and removing the cutting wastes which are produced by the cutting and removing processing and may be firmly adhered; a processing step of cutting and removing processing the defect portion with a probe; and a moving step of moving the cutting wastes by scanning the probe with a weaker pressing force than the pressing force at the time of cutting and processing within the removing processing areas of cutting wastes to conduct a cutting wastes removing process.

### RELATED APPLICATIONS

This application claims priority under 35 U.S.C. §119 to Japanese Patent Application No. JP2007-165984 filed Jun. 25, 2007, the entire content of which is hereby incorporated by reference.

### BACKGROUND OF THE INVENTION

1. Field of the Invention

The present invention relates to a photomask defect correction device and a photomask defect correction method involving subjecting a defect portion of a photomask, which is used when manufacturing a semiconductor, to cutting and removing processing to correct the photomask into a normal one.

2. Description of the Related Art

The photomask, which is used when manufacturing a semiconductor, becomes an original plate for a pattern, and hence after drawing a mask pattern on a mask substrate, an inspection of presence or absence of the defect portion is always conducted, and the correction of the defect portion is optionally carried out.

The photomask is drawn on the mask substrate with a drawing device based on drawing data designed in advance. With this, the photomask having a mask pattern drawn on the mask substrate is prepared. Further, after preparing the photomask, the presence or absence of the defect and location of the defect portions are inspected using a defect inspection device, and if any defect is present, defect correction processing with a photomask defect correction device is carried out before the photomask is transferred onto a wafer.

As the kinds of the defect of the mask pattern, for example, a projection which excessively projects from a desired pattern and becomes the projection, a recess such as a cutaway is caused in the desired pattern (intrusion), and the like are given. Those defect portion is corrected as follows. After the location of the defect portion is identified by the defect inspection device, the shape of the defect portion is recognized in detail by the photomask defect correction device and also removing processing is conducted with respect to the defect which becomes a projection, and about pattern lacking, a light-blocking film is formed on the recess portion to be corrected.

As methods of removing processing at this time, there are known various methods. However, as one of those, there is known a method involving using an atomic force microscope (AFM) to correct the defect portion (see, “Defect repair performance using the nanomachining repair technique,” 2003, Proc. of SPIE 5130, P520-P527, written by Y Morikawa, H. Kokubo, M. Nishiguchi, N. Hayashi, R. White, R. Bozak, and L. Trrill).

This method involves observing a predetermined area on the mask substrate with a probe having a probe at a tip thereof using AFM to specify in detail the defect portions of the mask pattern, and then the defect portions are subjected to the cutting and removing processing using the same probe device. In particular, this method is effective in a case where the defect portions excessively protrude from a desired pattern to form projection-like shapes.

However, the above-mentioned conventional method still involves the following problems.

According to the conventional method, the defect portion may be cut with the probe provided at tip of the probe device. However, at the time of cutting, cutting wastes are inevitably produced. The amount of produced cutting wastes differs depending on the cutting amount when the defect portion is cut. However, irrespective of the produced amount, the cutting wastes are scattered at the periphery of the processing area after the cutting and removing processing. In this case, the scattering state differs each time, and hence the cutting wastes may attach to places apart from the processing area and places close to the processing area. It is an actual state, however, that almost all the cutting wastes attach to the places close to the processing area. Note that, those cutting wastes may attach onto the mask substrate or onto the mask pattern.

In the above-mentioned non-patent document, there is no description about the cutting wastes. However, the photomask can not be used as it is where the cutting wastes are attached thereto, and hence it is necessary to conduct wet washing or dry ice washing to remove the cutting wastes. However, the cutting wastes scattered in the periphery of the processing area, in particular, the cutting wastes attached to the vicinity of processing area are not merely attached thereto, but there are many cases of being firmly adhered for some reason. For that reason, even if the above-mentioned washing processing is conducted, it was impossible to completely remove the cutting wastes. Hereinafter, “firmly adhered” refers to a case where the cutting wastes are so firmly adhered that the cutting wastes can not be easily removed by the washing.

Further, the photomask from which the cutting wastes are hard to be removed by the washing can not be used as the photomask, resulting in give up of the correction thereof. Then, the photomask is disposed and a new photomask is reprepared. Otherwise, the photomask is introduced into the photomask defect correction device and is subjected to washing to cut away the cutting wastes which could not be washed away. In either case, however, throughputs of the photomask largely degrade. Further, in a case of a half tone phase shift mask, film thickness reduction occurs by the washing, and hence allowable number of times of washing is limited. It is not desired, therefore, to carry out repeatedly additional works and washing.

Therefore, before conducting the washing, there was a need to conduct in advance releasing processing against the cutting wastes to be moved by applying an external force to the cutting wastes which may be firmly adhered to the photomask. Specifically, after completing the cutting and removing processing, the AFM observation is carried out again with the probe device to confirm the positions of the cutting wastes. Then, based on positional data, the probe is allowed to contact with the cutting wastes, which may be firmly adhered to the photomask, and scanning is performed by a weaker force than the force at the cutting so that the mask substrate being a base or the mask pattern are not influenced with the scanning to move the cutting wastes. In this way, there was a need to conduct the releasing operation for the cutting wastes firmly adhered between the cutting and removing processing and the washing.

Thus, it takes time, thereby being not able to conduct the operation efficiently. In particular, the cutting wastes releasing operation is performed by an operator by appropriately selecting the cutting wastes which may be firmly adhered to the photomask from many of the cutting wastes. For that reason, the operation largely depends on experiences and judgement of the operator. As a result, there was liable to cause a human error such as remaining of the cutting wastes after the washing. In this case, there was a need to conduct the releasing operation again for the firmly adhered cutting wastes, and hence not only taking time too much, but also a large load is burdened to the operator.

### SUMMARY OF THE INVENTION

The present invention has been made under the above-mentioned circumstances, and therefore has an object to provide a photomask defect correction device and a photomask defect correction method with which, after cutting the defect portion, it is possible to automatically and positively move and release the cutting wastes, which are produced at the time of cutting and which may be firmly adhered, without using human hands, and is also possible to perform an effective correction operation while preventing a human error without taking time as much as possible.

In order to attain the above-mentioned object of the invention, the present invention provides the following means.

According to the present invention, there is provided a photomask defect correction device for correcting a defect on a photomask including a substrate and a mask pattern formed on the substrate with a predetermined pattern by cutting and removing processing a projection type defect portion projected from the mask pattern on the substrate, based on observation data obtained through AFM observation of the photomask in advance by using an AFM probe,

the photomask defect correction device including:

a stage for fixing the photomask;
a probe device having a probe provided on a tip of the probe device, the probe being disposed opposingly to the substrate;
a moving means for relatively moving the substrate and the probe in a parallel direction of a surface of the substrate and in a vertical direction the surface of the substrate;
a displacement measuring means for measuring the displacement of the probe device;
an area setting section for setting a processing area for cutting and removing processing the defect portion based on the observation data, and for setting areas adjacent to the processing area as removing processing areas of cutting wastes for cutting and removing the cutting wastes which are produced by the cutting and removing processing and may be firmly adhered at least one of on the substrate and on the mask pattern; and
a control means for controlling the moving means while adjusting a pressing force of the probe device based on measurement results by the displacement measuring means to subject the defect portion to the cutting and removing processing, and for moving the cutting wastes which are produced at the cutting and removing processing,

in which the control means repeatedly scans the probe while pressing the probe with a predetermined force within the processing area to subject the defect portion to the cutting and removing processing, and thereafter scans the probe with a weaker pressing force than the pressing force at the time of cutting and processing within the removing processing areas of cutting wastes to conduct a cutting wastes removing process, thereby moving the cutting wastes.

Further, according to the present invention, there is provided a photomask defect correction method of correcting a defect on a photomask including a substrate and a mask pattern formed on the substrate with a predetermined pattern by cutting and removing processing a projection type defect portion projected from the mask pattern on the substrate, based on observation data obtained through AFM observation of the photomask in advance by using an AFM probe,

the photomask defect correction method including:
an area setting step of setting a processing area for cutting and removing processing the defect portion based on the observation data, and setting areas adjacent to the processing area as removing processing areas of cutting wastes for cutting and removing the cutting wastes which are produced by the cutting and removing processing and may be firmly adhered at least one of on the substrate and on the mask pattern;
a processing step of repeatedly scanning the probe while pressing the probe with a predetermined force within the processing area to subject the defect portion to the cutting and removing processing; and
a moving step of moving the cutting wastes, after the processing step, by scanning the probe with a weaker pressing force than the pressing force at the time of cutting and processing within the removing processing areas of cutting wastes to conduct a cutting wastes removing process.

In the photomask defect correction device and the photomask defect correction method according to the present invention, first, the area setting section recognizes the shape of the defect portion based on the observation data obtained in advance through AFM observation, and sets the processing area for cutting and removing processing the defect portion. Besides, the area setting section forecasts, at the same time, areas where the cutting wastes which are produced at the cutting and removing processing and which may be firmly adhered are scattered, and sets the removing processing areas of cutting wastes where the cutting waste may be firmly adhered. At this time, the removing processing areas of cutting wastes are set so as to adjacent to the processing area at least one of on the substrate and on the mask pattern.

After completing the area setting step, the control means controls the moving means to move the probe within the processing area which has been set in advance, and causes the probe to repeatedly scan within the area while pressing the probe with a predetermined force to conduct the processing step of cutting and removing processing the defect portion. At this time, the control means adjusts the pressing force of the probe based on the measurement results by the displacement measuring means, thereby being capable of cutting with a desired force and positively removing the defect portion without leaving the cuttings. Incidentally, the defect portion cut by the cutting and removing processing becomes the cutting wastes to be scattered at the periphery of the processing area to be firmly attached on the substrate or on the mask pattern. In particular, the cutting wastes attached to the vicinity of the processing may be not only attached but also in a state firmly adhered.

Therefore, after completing the cutting and removing processing of the defect portion, the control means exerts an external force to the cutting wastes which may be firmly adhered to move the cutting wastes, and the moving step for releasing the firm adhesion is successively performed after the processing step. First, the control means controls the moving means to move the probe within the removing processing areas of cutting wastes set in advance, and repeatedly scans the probe within the area while pressing the probe with a weaker force the force of the cutting and removing processing. In this way, the probe is scanned within the area where the scattering of the cutting wastes which may be firmly adhered is forecasted in advance, and the cutting waste which may be firmly attached actually existing within the area may be moved by exerting the external force thereto. With this operation, after the scattering, even if the cutting wastes were firmly adhered to the mask pattern after scattering for some reason, it is possible to release the firm adhesion.

Thus, by conducting treatment such as washing thereafter, the cutting wastes firmly adhered at the time of cutting and removing processing may be removed completely. In particular, different from the conventional method in which only the cutting wastes which may be firmly adhered are moved according to a judgement of an operator by himself/herself, the probe device is scanned repeatedly within the removing processing areas of cutting wastes which are set as a result of forecasting the area where the scattered cutting wastes may be firmly adhered. Therefore, the firmly adhered cutting wastes may be positively removed without depending on a manpower. In other words, conventionally, the cutting wastes to be moved are selected according to an experience or a judgement of the operator. However, according to this invention, irrespective of the judgement of the operator, all the firmly adhered cutting wastes which exist within the removing processing areas of cutting wastes may be moved. Thus, such a human error that the cutting wastes are left as a result may be eliminated, thereby being capable of conducting a positive correction operation.

Further, the processing area and the removing processing areas of cutting wastes are set in advance, and hence the cutting and removing processing and the movement of the cutting wastes may be automatically, successively performed. Thus, the operation time period may be reduced much than the conventional operation, thereby being capable of conducting an effective operation. Further, with regard to the movement of the cutting wastes, there is no case of troubling the operator as in the conventional method, there may reduce a burden borne by the operator. Further, in a case where the probe device is scanned within the removing processing areas of cutting wastes to move the cutting wastes which may be firmly adhered, the probe is pressed with a weaker force than the pressing force at the time of cutting and removing processing. Therefore, while preventing from exerting adverse effects such as damages by applying an excessive force with respect to the substrate and the mask pattern, only the cutting wastes which may be firmly adhered may be moved.

Further, based on the observation data, the removing processing areas of cutting wastes is set at the same timing with the processing area. Accordingly, after recognizing the shape of the defect portion and the edge of the mask pattern, the removing processing areas of cutting wastes may be set in advance. If the cutting wastes are produced much and the cutting wastes are attached to the vicinity of the edge of the mask pattern, in the conventional method, AFM observation is performed again after the cutting and removing processing. Accordingly, the cutting wastes obstruct so that it is sometime difficult to clearly recognize the edge of the mask pattern. For that reason, when moving the cutting wastes which may be firmly adhered, the probe is brought into contact with the edge of the mask pattern by mistake, and hence there is a fear of causing new defect portion such as a break.

However, as described above, after recognizing the shape of the defect portion and the edge of the mask pattern, the removing processing areas of cutting wastes are set, resulting in causing no deficiency as in the conventional method.

Further, according to a photomask defect correction device of the present invention, in the above-mentioned photomask defect correction device, the area setting section sets sizes and positions of the removing processing areas of the cutting wastes, based on at least one of a size of the processing area and a scanning direction at the time of cutting and removing processing.

Further, according to a photomask defect correction method of the present invention, in the above-mentioned photomask defect correction method, at the area setting step, sizes and positions of the removing processing areas of the cutting wastes are set based on at least one of a size of the processing area and a scanning direction at the time of cutting and removing processing.

In the photomask defect correction device and the photomask defect correction method according to the present invention, when setting the removing processing areas of cutting wastes, based on at least one condition of the size of the processing area and the scanning direction at the time of cutting and removing processing, the scattering areas of the cutting wastes are forecasted, and the removing processing areas of cutting wastes are set. For example, in a case where the processing area is set to a larger area because the defect portion is large, the cutting wastes which may be firmly adhered may scatter in the large area, and hence the removing processing areas of cutting wastes must be set to the larger area. Further, because the cutting wastes may scatter in a scanning direction of the probe device, the removing processing areas of cutting wastes are always arranged so as to adjacent on the scanning direction side of the processing area, and the areas must be set to be wider.

In this way, based on the size of the processing area and the scanning direction of the probe device, the removing processing areas of cutting wastes for moving the cutting wastes which may be firmly adhered are set at the optimum positions and to sizes, thereby being capable of effectively releasing the firm adhesion of the cutting wastes.

Further, according to a photomask defect correction device of the present invention, in the above-mentioned photomask defect correction device, the area setting section sets the removing processing areas of the cutting wastes so as to overlap with at least a part of the processing area.

Further, according to a photomask defect correction method of the present invention, in the above-mentioned photomask defect correction method, at the area setting step, the removing processing areas of the cutting wastes are set so as to overlap with at least a part of the processing area.

In the photomask defect correction device and the photomask defect correction method according to the present invention, when the removing processing areas of cutting wastes are set, the removing processing areas of cutting wastes may be set so as to overlap with parts of the processing area. When the defect portion is subjected to the cutting and removing processing, as the scanning of the probe device is repeatedly performed within the processing area, the produced cutting wastes are liable to scatter outside the processing area. However, the produced cutting wastes may stay within the processing area. Therefore, the removing processing areas of cutting wastes are caused to overlap with parts of the processing area, thereby being capable of releasing the firm adhesion of the cutting wastes stayed within the processing area. Note that, the removing processing areas of cutting wastes may be set so as to overlap with the entire processing area.

Further, according to a photomask defect correction device of the present invention, in the above-mentioned photomask defect correction device, when setting the removing processing areas of cutting wastes on the substrate, the area setting section sets the removing processing areas of cutting wastes so as to be spaced apart from the edge of the mask pattern with a predetermined distance.

Further, according to a photomask defect correction method of the present invention, in the above-mentioned photomask defect correction method, at the area setting step, when setting the removing processing areas of cutting wastes on the substrate, the removing processing areas of cutting wastes are set so as to be spaced apart from the edge of the mask pattern with a predetermined distance.

In the photomask defect correction device and the photomask defect correction method according to the present invention, when setting the removing processing areas of cutting wastes on the substrate, a border line of the removing processing areas of cutting wastes be set so as to be spaced apart from the edge of the mask pattern with a predetermined distance. Thus, when scanning the probe device within the removing processing areas of cutting wastes, the contact of the probe with the edge of the mask pattern by mistake may be positively prevented from occurring.

Further, according to a photomask defect correction device of the present invention, in the above-mentioned photomask defect correction device, when the area setting section sets the removing processing areas of cutting wastes on both the substrate and the mask pattern, the control means controls so that the scanning is performed earlier for the removing processing area of cutting wastes set on the mask pattern.

Further, according to a photomask defect correction method of the present invention, in the above-mentioned photomask defect correction method, at the area setting step, when the removing processing areas of cutting wastes are set on both the substrate and the mask pattern, at the moving step, the scanning is performed earlier for the removing processing area of cutting wastes set on the mask pattern.

In the photomask defect correction device and the photomask defect correction method according to the present invention, when setting the removing processing areas of cutting wastes, if the removing processing areas of cutting wastes are set on both the substrate and the mask pattern, the scanning is performed earlier within one of the removing processing areas of cutting wastes set on the mask pattern. The cutting wastes moved by the scanning may fall from on the mask pattern to the substrate. However, in this case, it is thought that the fallen cutting wastes may firmly adhere thereto again by the influence at the time of falling down. However, the scanning is next performed in the removing processing areas of cutting wastes set on the substrate, the fallen cutting wastes may also be moved to release the firm adhesion. Therefore, the operation for releasing the firm adhesion of the cutting wastes may easily positively be performed.

Further, according to a photomask defect correction device of the present invention, in the above-mentioned photomask defect correction device, when the probe is scanned in parallel with the edge of the mask pattern to subject the defect portion to the cutting and removing processing, the area setting section set one of the removing processing areas of cutting wastes on the mask pattern so as to adjacent to the defect portion, and sets the removing processing areas of cutting wastes so as to position on both sides of the defect portion in the parallel direction.

Further, according to a photomask defect correction method of the present invention, in the above-mentioned photomask defect correction method, at the processing step, when the probe is scanned in parallel with the edge of the mask pattern to subject the defect portion to the cutting and removing processing, at the area setting step, one of the removing processing areas of cutting wastes is set on the mask pattern so as to adjacent to the defect portion, and the removing processing areas of cutting wastes are set so as to position on both sides of the defect portion in the parallel direction.

In the photomask defect correction device and the photomask defect correction method according to the present invention, when subjecting the defect portion to the cutting and removing processing, if the probe is scanned in a parallel direction of the edge of the mask pattern, forecasting that the cutting wastes which may be firmly adhered may particularly scattered at three positions including on the mask pattern adjacent to the defect portion, and on the substrate at positions on both sides of the defect portion, the setting of the removing processing areas of cutting wastes is carried out. In this way, the cutting and removing processing areas of cutting wastes for moving the cutting wastes which may be firmly attached are set based on the scanning direction of the cutting and removing processing, the firm adhesion of the cutting wastes may be more positively released.

Further, a photomask defect correction device according to the present invention, in the above-mentioned photomask defect correction device, further includes a washing mechanism for washing a surface of the substrate after completing movement of the cutting wastes.

Further, a photomask defect correction method according to the present invention, in the above-mentioned photomask defect correction method, further includes, after the moving step, a washing step of washing a surface of the substrate after completing movement of the cutting wastes.

In the photomask defect correction device and the photomask defect correction method according to the present invention, after completing the scanning within the removing processing areas of cutting wastes which have been set, that is, after moving the cutting wastes to release the firm adhesion, the washing step of washing the surface of the substrate with the washing mechanism is carried out. As a result, the cutting wastes produced at the time of cutting and removing processing are completely removed. In particular, different from the conventional method in which a human error is liable to occur, the firm adhesion is released without fail for the cutting wastes which may be firmly adhered by being scattered at the periphery, thereby being capable of efficiently removing the cutting wastes.

According to the photomask defect correction device and the photomask defect correction method, after cutting the defect portion, it is possible to automatically and positively move and release the cutting wastes, which are produced at the time of cutting and which may be firmly attached, without using human hands, and is also possible to perform an effective correction operation while preventing a human error without taking time as much as possible

### BRIEF DESCRIPTION OF THE DRAWINGS

In the accompanying drawings:

FIG. 1 is a perspective view of a photomask to which correction is performed by a photomask defect correction device according to the present invention;

FIG. 2 is a block diagram illustrating a photomask defect correction device according to an embodiment of the present invention;

FIG. 3 illustrates one process for correcting a defect portion produced on a mask pattern by the photomask defect correction device of FIG. 1, in which relations among the defect portion, observation areas, processing areas, and removing processing areas of cutting wastes are illustrated.

FIG. 4 illustrates one process for correcting the defect portion produced on a mask pattern by the photomask defect correction device of FIG. 1, in which movement of a probe when AFM observation is performed within a set observation area is viewed from upward of a mask pattern;

FIG. 5 is a perspective view of the mask pattern and the defect portion, which are obtained by the observation illustrated in FIG. 4;

FIG. 6 illustrates one process for correcting the defect portion produced on the mask pattern by the photomask defect correction device of FIG. 1, in which movement of the probe when the defect portion is subjected to cutting and removing processing is viewed from upward of the mask pattern after the observation;

FIG. 7 is a perspective view illustrating the mask pattern after conducting the cutting and removing processing;

FIG. 8 illustrates a scattering state of the cutting wastes on the mask pattern and the substrate after the cutting and removing processing;

FIG. 9 illustrates a setting of removing processing areas of the cutting wastes, which are different from the setting areas of FIG. 3, and illustrates a state in which one of the removing processing areas of the cutting wastes, which are set on the substrate, is set to be wider;

FIG. 10 illustrates a setting of the removing processing areas of the cutting wastes, which is different from the setting area of FIG. 3, and illustrates a state in which the removing processing areas of the cutting wastes are overlapped with parts of the processing area set on the substrate;

FIG. 11 illustrates a setting of the removing processing areas of the cutting wastes, which is different from the setting area of FIG. 3, and illustrates a state in which the removing processing areas of the cutting wastes set on the substrate are overlapped with the entire processing area.

FIG. 12 illustrates a setting of the removing processing areas of the cutting wastes, which is different from the setting area of FIG. 3, and illustrates a state in which the removing processing areas of the cutting wastes set on the substrate are spaced apart from an edge of the mask pattern; and

FIGS. 13A and 13B illustrate modification examples of the present invention, in which FIG. 13A illustrates a state in which, based on a condition of the defect portion, three removing processing areas of the cutting wastes are set on the mask pattern, and FIG. 13B illustrates a state in which one removing processing areas of cutting wastes are set on the substrate, and two removing processing areas of the cutting wastes are set on the mask pattern.

### DETAILED DESCRIPTION OF THE PREFERRED EMBODIMENTS

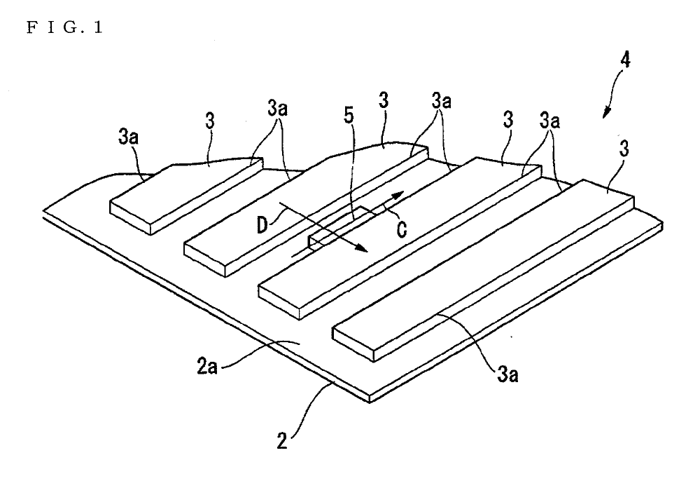

Hereinafter, description is made of an embodiment of a photomask defect correction device 1 and a photomask defect correction method according to the present invention with reference to FIG. 1 to FIG. 8. Note that, in this embodiment, description is made of a case as an example where an optical lever method is used.

The photomask defect correction device 1 according to this embodiment performs AFM observation of a photomask 4 shown in FIG. 1, which includes a substrate 2 and a light-blocking film mask pattern (hereinafter, simply referred to as mask pattern) 3 formed on the substrate 2 so as to have a given pattern, a projection shape of an excessive defect portion (hereinafter, simply referred to as defect portion) 5 projected from the mask pattern 3 is subjected to AFM observation to recognize a shape of the defect portion, and then the defect portion 5 is subjected to cutting and removing processing, to thereby correct the defect portion 5.

Note that, the photomask 4 is prepared by a drawing device (not shown), and the mask pattern 3 is drawn on the substrate 2 based on drawing data designed in advance. Further, the photomask 4 is inspected with a defect inspection device (not shown) after being prepared by the drawing device, and hence a position of the defect portion 5 has already been specified. Further, the substrate 2 of the photomask 4 is a optical transmitting portion and becomes a mask substrate, and is, for example, a glass or quartz substrate.

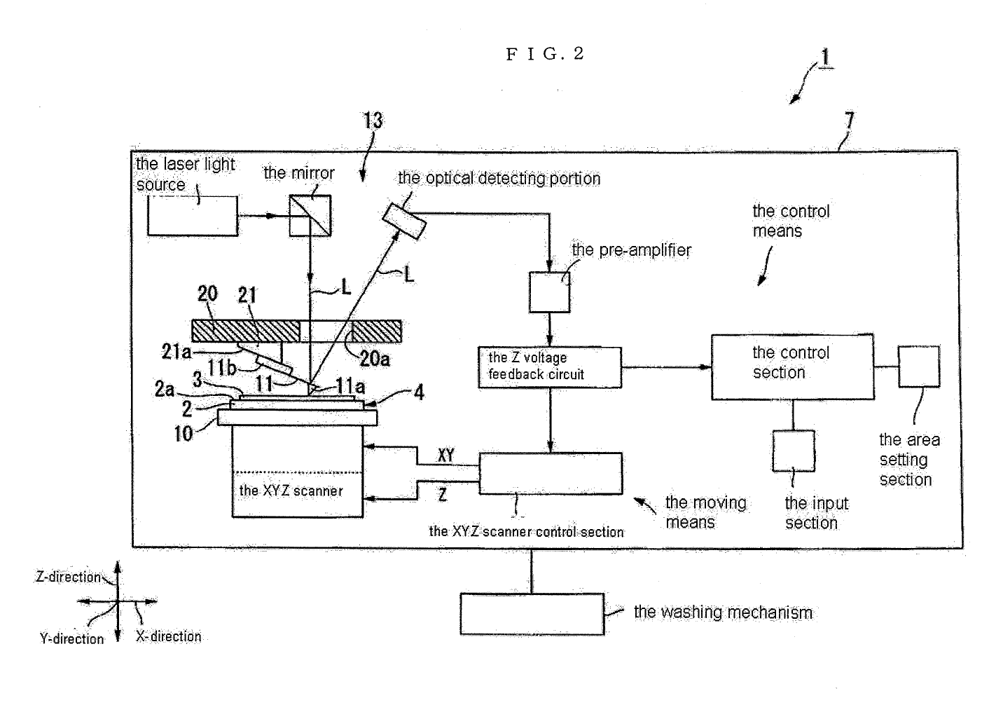

The photomask defect correction device 1 of this embodiment, as illustrated in FIG. 2, includes a defect cutting mechanism 7 and a washing mechanism 8.

The defect cutting mechanism 7 includes a stage 10 for fixing the photomask 4, a probe 11 having at a tip thereof a probe tip 11a provided so as to oppose to the substrate 2, a moving means for relatively moving the substrate 2 and the probe tip 11a in an XY direction which is parallel to the substrate surface 2a and in a Z direction which is perpendicular to the substrate surface 2a, a displacement measuring means 13 for measuring a displacement of the probe 11 (deformation), an area setting section 14 for setting a processing area E1 and removing processing areas E2 of cutting wastes which are described later, and a control means 15 for totally controlling the respective components.

The probe tip 11a is made of a hard material such as a diamond so that the defect portion 5 is easily cut away, and is formed so that a surface that abuts against the defect portion 5 at the cutting and removing processing forms a right angle (perpendicular) to the defect portion 5. Further, the probe 11 is made of silicon or the like, and is supported in a cantilever state by a body portion 11b. The probe device having a higher spring constant than the conventional one is used for the probe 11 so as to prevent a sufficient load necessary for processing from not being applied to an edge, which undergoes distortion due to processing resistance at the time of the cutting processing. The body portion 11b is detachably fixed using a wire or the like (not shown) to a mounting surface 21a of a slanted block 21 which is fixed to a holder portion 20. With this structure, the probe 11 is fixed while being inclined by a predetermined angle with respect to the substrate surface 2a.

The holder portion 20 is mounted to a frame (not shown) so as to be positioned upward of the substrate 2. Further, the holder portion 20 has an opening 20a formed therein, which allows a laser light L described later to enter into a reflecting surface (not shown) formed on a back surface the probe 11 and also allows the laser light L reflected on the reflecting surface to exit.

The stage 10 is mounted on the XYZ scanner 22, and the XYZ scanner 22 is mounted on a vibration-isolated table (not shown). The XYZ scanner 22 is, for example, a piezoelectric element, and is configured to minutely move in an XY direction and in a Z direction by being applied with a voltage from an XYZ scanner control section 23 including an XY scanning system and a z servo system. Specifically, the XYZ scanner 22 and the XYZ scanner control section 23 each function as the above-mentioned moving means 12.

Further, provided above the holder portion 20 are a laser light source 25 which emits the laser light L towards the reflecting surface formed on the back surface of the probe 11, and a optical detecting portion 27 which receives the laser light L reflected on the reflecting surface using a mirror 26. Note that, the laser light L emitted from the laser light source 25 passes through the opening 20a of the holder portion 20 to reach to the reflecting surface, and after being reflected on the reflecting surface, the laser light L enters the optical detecting portion 27 by passing through the opening 20a again.

The optical detecting portion 27 is, for example, a photodiode having an incident surface which is divided into two or four, and detects the displacement (deformation) of the probe 11 judging from an incident position of the laser light L. Then, the optical detecting portion 27 outputs the detected displacement of the probe 11 as a DIF signal to the pre-amplifier 28. Specifically, the laser light source 25, the mirror 26, and the optical detecting portion 27 each function as the displacement measuring means 13 for measuring the displacement of the probe 11.

Further, the DIF signal output from the optical detecting portion 27 is amplified by the pre-amplifier 28, and then transmitted to a Z voltage feedback circuit 29. The Z voltage feedback circuit 29 performs a feedback control of the XYZ scanner control section 23 so that the transmitted DIF signal becomes always constant. With this structure, when the substrate surface 2a is subjected to AFM observation, the distance (height) between the substrate 2 and the probe tip 11a may be controlled so that the displacement of the probe 11 becomes constant.

Further, the control section 30 is connected to the Z voltage feedback circuit 29, and the control section 30 is configured so as to obtain the observation data on the substrate surface 2a based on a signal for vertical movements from the Z voltage feedback circuit 29. With this structure, the mask pattern 3 formed on the substrate 2 and an image of the defect portion 5 of the mask pattern 3 may be obtained.

Specifically, the Z voltage feedback circuit 29 and the control section 30 each function as the control means 15. Note that, the control means 15 is set so as to perform AFM observation to recognize in detail the defect portion 5 being an object of the cutting and removing processing, and thereafter subsequently, to perform the cutting and removing processing of the defect portion 5.

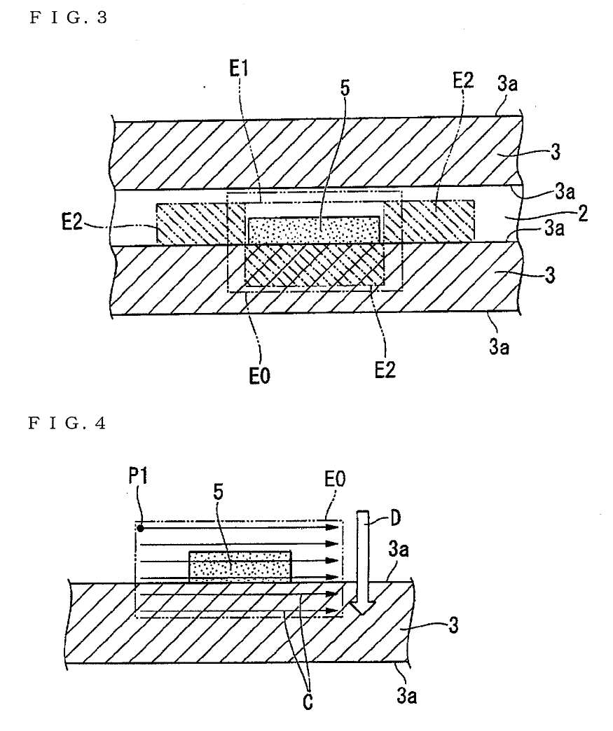

Further, an input section 31 through which an operator may input various information is connected to the control section 30, thereby being capable of freely setting the observation area E0, etc. through the input section 31 as illustrated in FIG. 3. With this structure, the operator may set the observation area E0 based on a rough positional data of the defect portion 5 identified by the defect inspection device. Then, the control section 30 is set so as to perform AFM observation within the observation area, if the observation area E0 is set.

Further, as illustrates in FIG. 2, the area setting section 14 is connected to the control section 30. The area setting section 14 has a function to recognize the shape of the defect portion 5 and the edge 3a of the mask pattern 3 based on the observation data obtained though AFM observation, and to automatically set the processing area E1 as illustrated in FIG. 3 to perform the cutting and removing processing of the defect portion 5. In addition, the area setting section 14 is configured to forecast areas where cutting wastes X which may be firmly adhered are to be scattered after setting the processing area E1, and to automatically set, at least one of on the substrate 2 and on the mask pattern 3, areas adjacent to the processing area E1 as removing processing areas E2 of cutting wastes where the scattered cutting wastes X may be firmly adhered as illustrated in FIG. 3

Further, the control section 30 is configured to, when the processing area E1 and the removing processing areas E2 of cutting wastes are set, control the moving means 12, while adjusting a pressing force of the probe 11 based on results of the measurement conducted by the displacement measuring means 13, to perform the cutting and removing processing of the defect portion 5, and to move the cutting wastes X which are produced at the time of cutting and removing processing and may be firmly adhered. In other words, the control section 30 is configured to control such that scanning is repeatedly conducted within the processing area E1 while pressing the probe tip 11a with a given force, the defect portion 5 is subjected to cutting and removing processing, thereafter the scanning is repeatedly conducted within the removing processing areas E2 of cutting wastes to perform the cutting wastes removing processing while pressing the probe tip 11a with a weaker pressing force than the pressing force at the time of the cutting and removing processing, and the cutting wastes X exist within one of the removing processing areas E2 of cutting wastes are moved. Detailed description of the above-mentioned operations will be made later.

Note that, in this embodiment, the control means 15 controls the respective components so that, when conducting AFM observation and the cutting and removing processing, as illustrated in FIG. 4, the probe tip 11a is scanned in a parallel direction with respect to the edge 3a of the mask pattern 3 (arrow C direction), and the scanning is performed in multiple times in a direction (arrow D direction) from a tip side of the defect portion 5 towards the mask pattern 3 side.

Further, the washing mechanism 8 is a mechanism which receives the photomask 4 on which the movement of the cutting wastes X is completed, and washes the substrate surface 2a by means of liquid washing, dry ice washing, or the like.

Next, hereinbelow, description is made of a photomask defect correction method which involves, after recognizing the shape of the defect portion 5 of the mask pattern 3 with the photomask defect correction device 1 constructed in this way, performing cutting and removing processing for correction.

The photomask defect correction method of the present invention includes an area setting step, a processing step, a moving step, and a washing step. The area setting step includes, after subjecting a defect portion 5 whose position is identified by the defect inspection device to AFM observation in more detail, setting a processing area E1 for cutting and removing processing the defect portion 5 based on observation data, and setting on a substrate 2 and on a mask pattern 3, areas adjacent to the processing area E1 as removing processing areas E2 of cutting wastes where scattered cutting wastes X may be firmly adhered. The processing step includes repeatedly scanning within the processing area E1 while pressing a probe tip 11a with a given force to perform the cutting and removing processing of the defect portion 5. The moving step includes repeatedly scanning within the removing processing areas E2 of cutting wastes to perform the cutting wastes removing processing while pressing the probe tip 11a with a weaker force than the pressing force at the time of the cutting and removing processing, and moving the cutting wastes X exist within the removing processing areas E2 of cutting wastes. The washing step includes a step of washing a substrate surface 2a on which movement of the cutting wastes X is completed. The respective steps are described in detail hereinbelow.

First, an initial setting is performed. Specifically, after fixing a photomask 4 on a stage 10, positions of a laser light source 25a and a optical detecting portion 27, a mounting state of a probe 11, and the like are adjusted so that a laser light L positively enters a reflecting surface of the probe 11, and further, the reflected laser light L positively enters the optical detecting portion 27. Subsequently, an operator specifies as an observation area E0, as illustrated in FIG. 3 and FIG. 4, through an input section 31, a periphery of the defect portion 5 whose position is identified by the defect inspection device.

After completing the initial setting, observation is started.

When the observation is started, the control means 15 causes the probe 11 to conduct scanning within the specified observation area E0 to obtain an observation image through AFM observation, and recognizes the shape of the defect portion 5 in detail.

Specifically describing, first, an XYZ scanner 22 is driven to move the probe tip 11a to a point P1 shown in FIG. 4. At the point P1, the probe tip 11a and the substrate 2 are allowed to approach each other, and the probe tip 11a and the mask pattern 3 are brought into contact with each other with a minute force. At this time, as the probe tip 11a approaches to the mask pattern 3, the probe 11 gradually bends to be displaced. Thus, based on this displacement, detection may be made with high precision as to whether or not the probe tip 11a is brought into contact with the mask pattern 3 with a minute force.

Subsequently, the XYZ scanner 22 is driven to allow the probe tip 11a to scan in a parallel direction (arrow C direction) with respect to the edge 3a of the mask pattern 3, while controlling the height of the XYZ scanner 22 so that the displacement of the probe 11 becomes constant, and the scanning is performed repeatedly in multiple times in a direction from a leading end side of the defect portion 5 towards the mask pattern 3 (arrow D direction). At this time, depending on irregularities, the probe 11 tends to bend and displace. Accordingly, the position of the incident laser light L entering the optical detecting portion 27 differs. Then, the optical detecting portion 27 outputs a DIF signal in accordance with displacement of the incident position to a pre-amplifier 28. The output DIF signal is amplified by the pre-amplifier 28, and then transmitted to the Z voltage feedback circuit 29.

The Z voltage feedback circuit 29 minutely moves the XYZ scanner 22 in a Z direction by the XYZ scanner control section 23 so that the DIF signal transmitted becomes constant (that is, the displacement of the probe 11 becomes constant), to thereby conduct a feedback control. With this operation, the scanning may be carried out with a state in which the height of the XYZ scanner 22 is controlled so that the displacement of the probe 11 becomes constant. Further, the control section 30 may conduct the surface observation within the observation area E0 based on a signal for vertically moving the XYZ scanner 22 by the Z voltage feedback circuit 29. As a result, within the observation area E0, there may be obtained image data of parts of the mask pattern 3 and the defect portion 5, and hence the shape of the defect portion 5 may be recognized in detail.

As a result, the size of the defect portion 5, for example, as illustrated in FIG. 5, a projection height H of 100 nm, a width W of 300 nm, and a thickness T of 100 nm may be recognized.

After the completion of AFM observation, the area setting section 14 recognizes the shape of the defect portion 5 based on the observation data obtained through AFM observation, and sets the processing area E1 for cutting and removing processing the defect portion 5. Further, the area setting section 14, at the same time, forecasts areas where the cutting wastes X which may be firmly adhered are to be scattered at the time of cutting and removing processing to set the removing processing areas E2 of cutting wastes.

In this embodiment, from the scanning direction of the probe 11 at the time of cutting and removing processing, the areas where the cutting wastes X which may be firmly adhered are to be scattered are forecasted. Then, one point on the mask pattern 3 adjacent to the defect portion 5 and two points on the substrate 2 positioned on both sides of the defect portion 5 in the scanning direction of the probe 11 at the time of cutting and removing processing are set as the removing processing areas E2 of cutting wastes. Description is made by giving as an example a case of three points in total as described above.

After completing the area setting step, the control means 15 controls the moving means 12 to move the probe 11 within the processing area E1 set a short while ago, and causes the scanning to be repeatedly performed within the area while pressing the probe tip 11a with a predetermined force to perform the processing step involving the cutting and removing processing the defect portion 5.

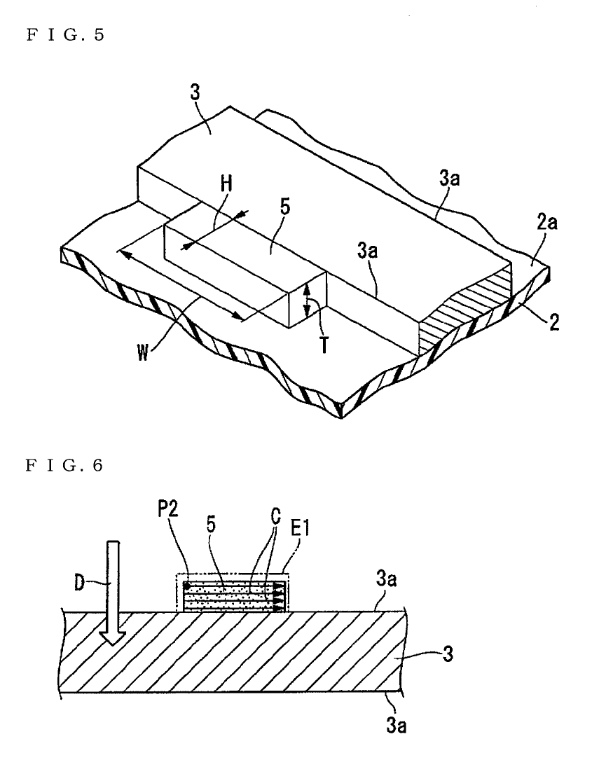

Specifically describing, first, the XYZ scanner 22 is driven to move the probe tip 11a to a point P2 shown in FIG. 6, and at the point P2, the probe tip 11a and the substrate 2 are allowed to approach each other, and the probe tip 11a and the mask pattern 3 are brought into contact with each other with a predetermined force. At this time, as the probe tip 11a is being pressed, the probe 11 gradually bends to be displaced. Thus, based on this displacement, it is possible to positively press the probe tip 11a with a predetermined force.

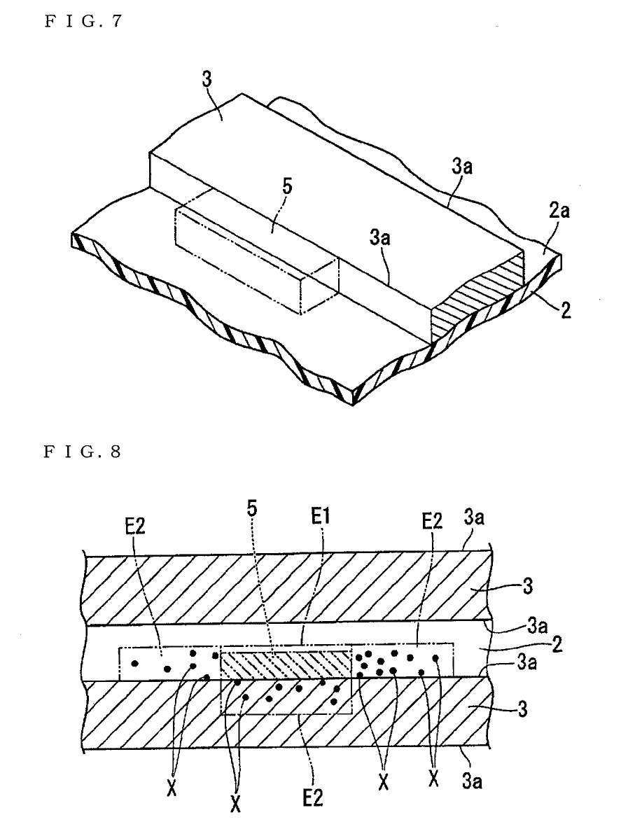

Next, while controlling the pressing force, the XYZ scanner 22 is driven to scan the probe tip 11a in a parallel direction (arrow C direction) with respect to the edge 3a of the mask pattern 3, and as illustrated in FIG. 6, the scanning is performed in multiple times in a direction (arrow D direction) from the tip side of the defect portion 5 towards the mask pattern 3. With this operation, the defect portion 5 may be gradually cut, and as illustrated in FIG. 7, the entire defect portion 5 may be cut and removed. In particular, the cutting and removing processing is performed from the tip side of the defect portion 5, the processing is carried out with small cutting resistance, thereby being capable of performing the cutting with efficiently and a short period of time.

Note that, when performing the cutting and removing processing, it is preferred to perform the cutting and removing processing so as to cut the substrate surface 2a a little (about several nm). Doing so, it is possible to positively remove the defect portion 5 without leaving.

Incidentally, during the processing step, the defect portion 5 which has been cut through the cutting and removing processing, as illustrated in FIG. 8, becomes the cutting wastes X and scatters on the substrate 2 or on the mask pattern 3 in the periphery of the processing area E1 to adhere thereon. In particular, the cutting wastes X attached to the vicinity of the processing area E1 may be not only attached but also in a state firmly attached.

Therefore, after completing the cutting and removing processing of the defect portion 5, the control means 15 performs applying an external force to the cutting wastes X which may firmly adhere to cause the cutting wastes to move, and performs the moving step for releasing the firm adhesion successively following the processing step. First, the control means 15 controls the moving means 15 to cause the probe 11 to move to the removing processing areas E2 of cutting wastes set in advance, and the scanning is performed repeatedly within the area while pressing the probe tip 11a with a weaker force than the force at the time of cutting and removing processing.

At this time, first, the scanning within one of the removing processing area E2 of cutting wastes which has been set on the mask pattern 3 is performed. With this scanning operation, it is possible to move the cutting wastes X actually exist within one of the removing processing areas E2 of cutting wastes, which has been set on the mask pattern 3, by applying an external force to the cutting wastes X. With this, even if the cutting wastes X were firmly adhered to the mask pattern 3 after scattering for some reason, it is possible to release the firm adhesion. Note that, the setting of the height of the probe 11 is performed using a surface of the mask pattern 3 as a reference height “0”.

Subsequently, the control means 15 moves the probe 11 one after another to two points of the removing processing areas E2 of cutting wastes set on the substrate 2, and similarly scans the probe 11 within the area. With this operation, after the scattering, even if the cutting wastes X are firmly adhere to the substrate 2, it is similarly possible to release the firm adhesion. Note that, in a case of transferring from one of the removing processing areas E2 of cutting wastes set on the mask pattern 3 to the removing processing areas E2 of cutting wastes set on the substrate 2, the height of the probe 11 may be set by reducing a thickness T of the defect portion 5 (−100 nm) from the height set a short while ago to.

Then, after completing the scanning within all the removing processing areas E2 of cutting wastes, the photomask 4 is delivered to the washing mechanism 8. Then, the washing mechanism 8 washes the substrate surface 2a by means of liquid washing, dry ice washing, or the like. As a result, the cutting wastes X produced at the time of cutting and removing processing may be removed completely.

In particular, according to the photomask defect correction device 1 of this embodiment and the photomask defect correction method, different from the conventional method in which only the cutting wastes X which may be firmly adhered are moved according to a judgement of an operator by himself/herself, the probe 11 is scanned repeatedly within the removing processing areas E2 of cutting wastes which are set as a result of forecasting the area where the scattered cutting wastes X may be firmly adhered. Therefore, the firmly adhered cutting wastes X may be positively removed without depending on a manpower. In other words, conventionally, the cutting wastes X to be moved are selected according to an experience or a judgement of the operator. However, according to this embodiment, irrespective of the judgement of the operator, all the firmly adhered cutting wastes X which exist within the removing processing areas E2 of cutting wastes may be moved. Thus, such a human error that the cutting wastes X are left as a result may be eliminated, thereby being capable of conducting a positive correction operation.

Further, the processing area E1 and the removing processing areas E2 of cutting wastes are set in advance, and hence the cutting and removing processing and the movement of the cutting wastes X may be automatically, successively performed. Thus, the operation time period may be reduced much than the conventional operation, thereby being capable of conducting an effective operation. Further, with regard to the movement of the cutting wastes X, there is no case of troubling the operator as in the conventional method, there may reduce a burden borne by the operator.

Further, in a case where the probe 11 is scanned within the removing processing areas E2 of cutting wastes to move the cutting wastes X which may be firmly adhered, the probe tip 11a is pressed with a weaker force than the pressing force at the time of cutting and removing processing. Therefore, while preventing from exerting adverse effects such as damages by applying an excessive force with respect to the substrate 2 and the mask pattern 3, only the cutting wastes X which may be firmly adhered may be moved.

Further, based on the observation data, the removing processing areas E2 of cutting wastes is set at the same timing with the processing area E1. Accordingly, after recognizing the shape of the defect portion 5 and the edge 3a of the mask pattern 3, the removing processing areas E2 of cutting wastes may be set in advance. If the cutting wastes X are produced much and the cutting wastes X are attached to the vicinity of the edge 3a of the mask pattern 3, in the conventional method, AFM observation is performed again after the cutting and removing processing. Accordingly, the cutting wastes X obstruct so that it is sometime difficult to clearly recognize the edge 3a of the mask pattern 3. For that reason, when moving the cutting wastes X which may be firmly adhered, the probe tip 11a is brought into contact with the edge 3a of the mask pattern 3 by mistake, and hence there is a fear of causing new defect portion such as a break.

However, as described above, after recognizing the shape of the defect portion 5 and the edge 3a of the mask pattern 3, the removing processing areas E2 of cutting wastes are set, resulting in causing no deficiency as in the conventional method. In this way, the photomask defect correction device 1 and the photomask defect correction method according to this embodiment are particularly effective for a case where the cutting wastes X are produced much.

In addition, when moving the cutting wastes X which may be firmly adhered, the scanning is performed earlier within one of the removing processing areas E2 of cutting wastes set on the mask pattern 3. The cutting wastes X, which are moved by the scanning, may fall from on the mask pattern 3 to the substrate 2. However, in this case, it is thought that the fallen cutting wastes X may firmly adhere thereto again by the influence at the time of falling down. However, the scanning is next performed in the removing processing areas E2 of cutting wastes set on the substrate 2, the fallen cutting wastes X may also be moved to release the firm adhesion. Therefore, the operation for releasing the firm adhesion of the cutting wastes X may easily positively be performed.

As described above, according to the photomask defect correction device 1 and the photomask defect correction method of this embodiment, after cutting the defect portion 5, the cutting wastes X which may be firmly adhered, which are produced at the time of the cutting, may be automatically, positively moved to release the firm adhesion without an aid of manpower. As a result, while preventing a human error from occurring, it is possible to effectively conduct the correction operation without spending time as much as possible.

Note that, a technical scope of the present invention is not limited to the above-mentioned embodiment, and various modifications may be made without departing from the purpose and the scope of the present invention.

For example, in the above-mentioned embodiment, the scanning method is employed in which the substrate 2 side is moved in a three-dimensional direction, but is not limited to the above-mentioned case, the probe 11 side may be moved in the three-dimensional direction. Further, there may employ a structure in which the probe 11 side is moved in a Z direction and the substrate 2 side is moved in an XY direction. Even in either case, only the scanning method differs, thereby being capable of taking the same operational effect as that of the above-mentioned embodiment.

Further, in the above-mentioned embodiment, it employs a structure in which, through the opening 20a formed in the holder portion 20, the laser light L is allowed to enter into the probe 11, and the reflected laser light L is allowed to outgo, but is not limited to this case. For example, the holder portion 20 may be made of a material which is optically transparent (for example, glass), and the opening 20a may be omitted.

Further, in the above-mentioned embodiment, the displacement measuring means 13 detects the displacement of the probe 11 using an optical lever method, it is not limited to the optical lever method, for example, there may employ a self detection method in which the probe 11 itself includes a displacement detection function (for example, piezoelectric resistance element).

Further, in the above-mentioned embodiment, there is exemplified a case where at total three points including one point on the mask pattern 3 and two points on the substrate, the removing processing areas E2 of cutting wastes are set, but not limited to this example, the removing processing areas E2 of cutting wastes may be set optionally at appropriately depending on its circumstances.

In particular, it is preferred that, based on at least one condition of the size of the processing area E1 and the scanning direction at the time of cutting and removing processing, the scattering areas of the cutting wastes X be forecasted, and the removing processing areas E2 of cutting wastes be set.

For example, in a case where the processing area E1 is set to a larger area because the defect portion 5 is large, the cutting wastes X which may be firmly adhered may scatter in the large area, and hence the removing processing areas E2 of cutting wastes must be set to the larger area. Further, because the cutting wastes X may scatter in a scanning direction of the probe 11, the removing processing areas E2 of cutting wastes are always arranged so as to adjacent on the scanning direction side of the processing area E1, and the areas E2 must be set to be wider. In this way, based on the size of the processing area E1 and the scanning direction of the probe 11, the removing processing areas E2 of cutting wastes for moving the cutting wastes X which may be firmly adhered are set at the optimum positions and to sizes, thereby being capable of effectively releasing the firm adhesion of the cutting wastes X.

Therefore, in the case of the above-mentioned embodiment, as illustrated in FIG. 9, at the time of cutting and removing processing, one of the removing processing areas E2 of cutting wastes which is positioned on the scanning direction of the probe 11 is preferably set to be wider.

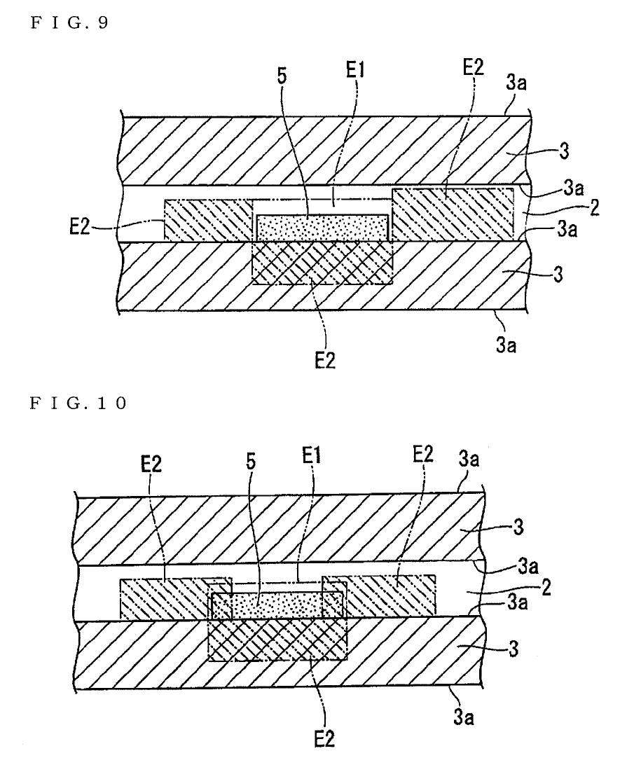

Further, in the above-mentioned embodiment, when the removing processing areas E2 of cutting wastes are set, as illustrated in FIG. 10, the removing processing areas E2 of cutting wastes may be set so as to overlap with parts of the processing area E1. When the defect portion 5 is subjected to the cutting and removing processing, as the scanning of the probe 11 is repeatedly performed within the processing area E1, the produced cutting wastes X are liable to scatter outside the processing area E1. However, the produced cutting wastes X may stay within the processing area E1. Therefore, the removing processing areas E2 of cutting wastes are caused to overlap with parts of the processing area E1, thereby being capable of releasing the firm adhesion of the cutting wastes X stayed within the processing area E1.

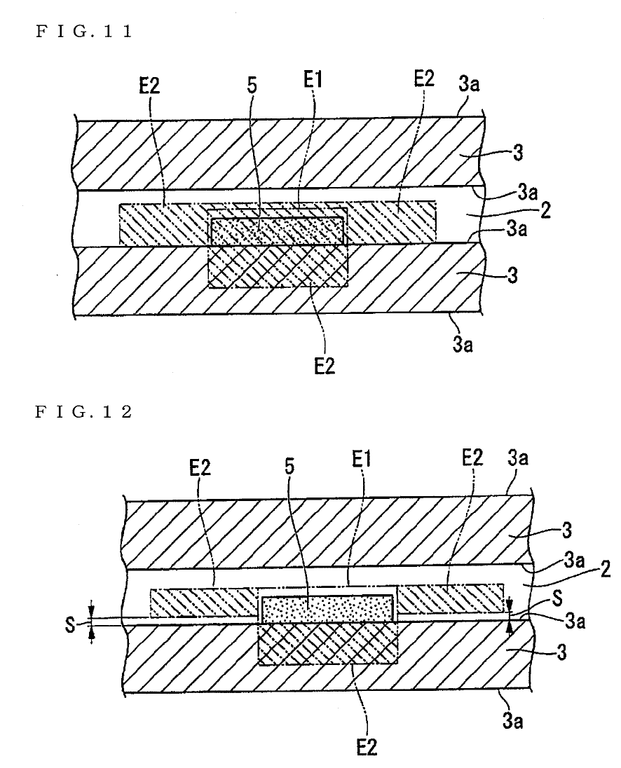

Note that, as illustrated in FIG. 11, the removing processing areas E2 of cutting wastes may be set so as to overlap with the entire processing area E1. In this case, the above-mentioned effect may be remarkably attained.

Further, in the above-mentioned embodiment, when setting the removing processing areas E2 of cutting wastes on the substrate 2, as illustrated in FIG. 12, it is preferred that a border line of the removing processing areas E2 of cutting wastes be set so as to be spaced apart from the edge 3a of the mask pattern 3 with a predetermined distance S (for example, about 10 nm). Thus, when scanning the probe 11 within the removing processing areas E2 of cutting wastes, the contact of the probe tip 11a with the edge 3a of the mask pattern 3 by mistake may be positively prevented from occurring.

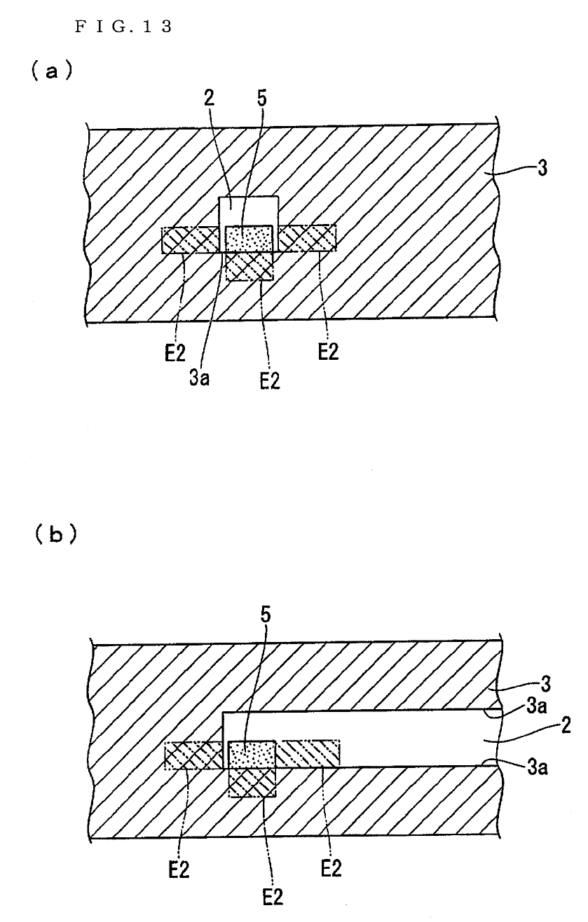

Further, in the above-mentioned embodiment, a case in which the defect portion 5 is caused on the mask pattern 3 patterned in a line shape is taken as an example, but is not limited to the case. As illustrated in FIG. 13A, even in a case where the mask pattern 3 is patterned so as to expose the substrate 2 to form a hole in a substantially square, and the defect portion 5 is caused therein, the present invention may be adopted thereto. In this case, for example, three removing processing areas E2 of cutting wastes may be set on the mask pattern 3. Even in this case too, the similar operational effect may be attained.

Further, even in a case where the mask pattern 3 is patterned as illustrated in FIG. 13B, the present invention may similarly be adopted. In this case, for example, one removing processing area E2 of cutting wastes is set on the substrate 2, and also two removing processing areas E2 of cutting wastes may be set on the mask pattern 3. Even in this case too, the similar operational effect may be attained.

What is claimed is:

1. A photomask defect correction device for correcting a defect on a photomask including a substrate and a mask pattern formed on the substrate with a predetermined pattern by cutting and removing processing a projection type defect portion projected from the mask pattern on the substrate, based on observation data obtained through AFM observation of the photomask in advance by using an AFM probe,
the photomask defect correction device comprising:
a stage for fixing the photomask;
a probe device having a probe provided on a tip of the probe device, the probe being disposed opposingly to the substrate;
a moving means for relatively moving the substrate and the probe in a parallel direction of a surface of the substrate and in a vertical direction the surface of the substrate;
a displacement measuring means for measuring the displacement of the probe device;
an area setting section for setting a processing area for cutting and removing processing the defect portion based on the observation data, and for setting areas adjacent to the processing area as removing processing areas of cutting wastes for cutting and removing the cutting wastes which are produced by the cutting and removing processing and may be firmly adhered at least one of on the substrate and on the mask pattern; and
a control means for controlling the moving means while adjusting a pressing force of the probe device based on measurement results by the displacement measuring means to subject the defect portion to the cutting and removing processing, and for moving the cutting wastes which are produced at the cutting and removing processing,
wherein the control means repeatedly scans the probe while pressing the probe with a predetermined force within the processing area to subject the defect portion to the cutting and removing processing, and thereafter scans the probe with a weaker pressing force than the pressing force at the time of cutting and processing within the removing processing areas of cutting wastes to conduct a cutting wastes removing process, thereby moving the cutting wastes.

2. A photomask defect correction device according to claim 1, wherein the area setting section sets sizes and positions of the removing processing areas of the cutting wastes, based on at least one of a size of the processing area and a scanning direction at the time of cutting and removing processing.

3. A photomask defect correction device according to claim 1, wherein the area setting device sets the removing processing areas of the cutting wastes so as to overlap with at least a part of the processing area.

4. A photomask defect correction device according to claim 1, wherein, when setting the removing processing areas of cutting wastes on the substrate, the area setting section sets the removing processing areas of cutting wastes so as to be spaced apart from the edge of the mask pattern with a predetermined distance.

5. A photomask defect correction device according to claim 1, wherein, when the area setting section sets the removing processing areas of cutting wastes on both the substrate and the mask pattern, the control means controls so that the scanning is performed earlier for the removing processing area of cutting wastes set on the mask pattern.

6. A photomask defect correction device according to claim 1, wherein, when the probe is scanned in parallel with the edge of the mask pattern to subject the defect portion to the cutting and removing processing, the area setting section set one of the removing processing areas of cutting wastes on the mask pattern so as to adjacent to the defect portion, and sets the removing processing areas of cutting wastes so as to position on both sides of the defect portion in the parallel direction.

7. A photomask defect correction device according to claim 1, further comprising a washing mechanism for washing a surface of the substrate after completing movement of the cutting wastes.

8. A photomask defect correction method of correcting a defect on a photomask including a substrate and a mask pattern formed on the substrate with a predetermined pattern by cutting and removing processing a projection type defect portion projected from the mask pattern on the substrate, based on observation data obtained through AFM observation of the photomask in advance by using an AFM probe,
the photomask defect correction method comprising:
an area setting step of setting a processing area for cutting and removing processing the defect portion based on the observation data, and setting areas adjacent to the processing area as removing processing areas of cutting wastes for cutting and removing the cutting wastes which are produced by the cutting and removing processing and may be firmly adhered at least one of on the substrate and on the mask pattern;
a processing step of repeatedly scanning the probe while pressing the probe with a predetermined force within the processing area to subject the defect portion to the cutting and removing processing; and
a moving step of moving the cutting wastes, after the processing step, by scanning the probe with a weaker pressing force than the pressing force at the time of cutting and processing within the removing processing areas of cutting wastes to conduct a cutting wastes removing process.

9. A photomask defect correction method according to claim 8, wherein, at the area setting step, sizes and positions of the removing processing areas of the cutting wastes are set based on at least one of a size of the processing area and a scanning direction at the time of cutting and removing processing.

10. A photomask defect correction method according to claim 8, wherein, at the area setting step, the removing processing areas of the cutting wastes are set so as to overlap with at least a part of the processing area.

11. A photomask defect correction method according to claim 8, wherein, at the area setting step, when setting the removing processing areas of cutting wastes on the substrate, the removing processing areas of cutting wastes are set so as to be spaced apart from the edge of the mask pattern with a predetermined distance.

12. A photomask defect correction method according to claim 8, wherein, at the area setting step, when the removing processing areas of cutting wastes are set on both the substrate and the mask pattern, at the moving step, the scanning is performed earlier for the removing processing area of cutting wastes set on the mask pattern.

13. A photomask defect correction method according to claim 8, wherein,
a photomask defect correction method according to claim 8, further comprising, after the moving step, a washing step of washing a surface of the substrate after completing movement of the cutting wastes.
